(19) United States
(12) Patent Application Publication
(10) Pub. No.: US 2010/0066376 A1
(43) Pub. Date: Mar. 18, 2010

(54) METHOD FOR TESTING A PROTECTIVE DEVICE, A PROTECTIVE DEVICE, AND TEST DEVICE

(75) Inventor: Ulrich Klapper, Rankweil (AT)

Correspondence Address: Workman Nydegger;1000 Eagle Gate Tower, 60 East South Temple, Salt Lake City, UT, 84111, US

(73) Assignee: Omicron Electronics GmbH, Klaus (AT)

(21) Appl. No.: 12/535,813

(22) Filed: Aug. 5, 2009

(30) Foreign Application Priority Data
Sep. 16, 2008 (EP) 08 016 271.2

(51) Int. Cl. G01R 31/327; H02H 3/00

(52) U.S. Cl. 324/418; 361/1

(57) ABSTRACT

A method for testing a protective device as well as a correspondingly configured protective device and test device are provided.

### CROSS-REFERENCE TO RELATED APPLICATIONS

This application claims the benefit of earlier filed European Patent Application No. 08 016 271.2, filed Sep. 16, 2008, the disclosure of which is incorporated herein in its entirety.

### BACKGROUND OF THE INVENTION

The present invention relates to a method for testing a protective device for an electrical power grid, a protective device for an electrical power grid and a test device for testing the protective device.

### BRIEF SUMMARY OF THE INVENTION

According to an embodiment of the present invention a method for testing a protective device for an electrical power grid is provided. According to the method an operating procedure of the protective device is tested. During an operation of the protective device for protecting the power grid the operating procedure requires a specific operating period, i.e., a specific amount of time for operating. During the test method the operating procedure is tested in a shorter period than the operating period of the operating procedure. This may be accomplished by for example operating a timing device of the protective device in an accelerated manner.

Protective devices, for example protective relays, of electrical power devices and equipment are required to work reliably to reduce the probability of blackouts or breakdowns of a power supply or to keep the probability of blackouts or breakdowns on a constant value even with an increasing energy demand. For this reason it is important to verify an accurate mode of operation of these protective devices with a high precision and a short measurement period or verify period.

Therefore, according to the above-described embodiment, operating procedures of the protective device are executed or tested in a shorter period during the test of the protective device, that means that they are executed faster than in real time, and therefore the whole test of the protective device can be executed in a shorter period compared with a test of the protective device according to the prior art. Therefore, according to the embodiment of the present invention, the test of the protective device is performed faster than in real time.

Speeding up the operating procedure of the protective device during the test can be achieved for example by operating the timing device of the protective device, which is used by the protective device for example for measuring specific predetermined periods, faster than during a regular operating procedure. For example, the timing device can be operated faster by increasing a clock frequency of the timing device.

Decreasing a testing time is especially important in the area of modern protective relays, as in this area a significantly larger number of test cases have to be tested. The required testing time increases significantly if commonly used periods of a regular operation according to the prior art of the protective device for the pre-failure, failure, and post-failure situations in a real power grid are considered. By dramatically reducing these periods according to the above-defined embodiment, even modern protective relays can be tested within a tolerable timing frame.

According to another embodiment the protective device can be reconfigured or switched into a test mode for testing the protective device, in which the timing device of the protective device is operated in an accelerated manner.

The protective device may comprise a low pass filter which couples the protective device to the power grid. During testing of the protective device this low pass filter may be bypassed.

By bypassing the low pass filter during the test of the protective device, high frequency data streams can be transmitted during the test of the protective device to the protective device for testing the protective device with these data streams. The data streams may comprise test patterns for testing the protective device. The faster these data streams can be received by the protective device, the faster the corresponding tests of the protective device can be executed, thus accelerating the procedure for testing the protective device.

The protective device may comprise either an analog interface or a digital interface (for example an interface according to IEC 61850-9-2) via which the protective device may be coupled to the power grid or via which the protective device can be tested. In case of a digital interface a converter is present between the power grid and the protective device providing the digital interface with data. Such a converter may be present inside the protective device if the protective device comprises an analog interface.

The use of a digital interface enables the digital interface to be configured especially according to requirements for a fast and convenient testing of the protective device. The digital interface may be a standardized digital interface as a majority of the tests to be conducted consists of digital test patterns. The corresponding test replies may be also digital. Furthermore, the protective device can also be tested according to the above-defined embodiment if the protective device comprises an analog interface.

During a test the protective device may be coupled to the test device exclusively. This can be achieved by a change over switch selectively coupling the protective device either to the power grid or to the testing device.

According to another embodiment, each next test step (sample) can be processed once the preceding test step is completely executed. That means, by using the digital interface each next sample (from the testing device) is requested by the protective device once the required computing operations (for handling the preceding sample) are completed in the protective device.

Conventionally, in some test cases a protective device waits for a predetermined period (or in case of a digital interface for a specific number of samples) before reacting. The result of a test can be verified after this predetermined period. For example, if it is specified that, in case of an failure, the protective device has to activate a power switch after a predetermined period, conventionally, it is only possible to verify after this predetermined period (or after a corresponding number of samples) if an instruction for activating the power switch was issued from the protective device at an appropriate point in time or not. If, according to the above-defined embodiment, the protective device is operated in an accelerated manner, such a test step can be evaluated earlier as soon as it is detected that the instruction for activating the power switch was issued (after an appropriate period). This means that according to the above-defined embodiment the testing device does not wait for the predetermined period, but instead the corresponding test step can be evaluated as being successfully as soon as the success determining result is present (in the example above, as soon as the instruction for switching the power switch is present). Thus, the whole test of the protective device can be accelerated.

For conducting the test a handshake type method can be used such that the data (for example the samples) can be provided to the protective device in a speed the protective device is adapted to process the data. Thus, a faster testing compared to the prior art can be accomplished even if the timing device is not operated in an accelerated manner. In this context a sample means a digitalized current or voltage value of an electrical power grid at a specific point in time. This sample can be simulated by a testing equipment.

Testing the protective device may comprise supplying of test currents or test voltages to the protective device as well as verifying of algorithms running on the protective device. Verifying the algorithms may comprise a verification of parameters or setting values.

Especially, in this case, samples are supplied (as test patterns) to the protective device and the corresponding test replies are evaluated. Typically, the protective device may not be completely busy for the whole time with computing operations and therefore these tests may be conducted faster as according to the prior art, especially if a digital interface is present at the protective device and especially if a handshake procedure is used. In a testing of a protective device according to a prior art testing, for example, 80 samples can be supplied to the protective device every 20 ms, which means 4000 samples can be applied to the protective device per second. Depending on the maximum clock speed of the protective device, this sample rate per second can be increased significantly according to the above-defined embodiment.

According to another embodiment, a protective device for an electrical power grid is provided. The protective device comprises a timing device. The protective device is adapted to conduct an operating procedure for protecting the power grid. This operating procedure requires a specific operating period when the protective device conducts the operating procedure for protecting the power grid. The protective device is furthermore adapted to be switchable or reconfigurable into a test mode, in which the protective device operates the timing device in an accelerated manner such that the operating procedure can be tested in a shorter period compared with the operating period.

According to yet another embodiment of the present invention a testing device is provided for testing the protective device defined above.

According to an embodiment of the testing device, the testing device is adapted to be switchable or reconfigurable in either a first test mode or in a second test mode. In the first test mode the testing device tests the protective device in real time, that means an operating procedure of the protective device is tested in the same period (operating period) the protective device requires for conducting the operating procedure during an operation of the protective device for protecting the power grid. In the second test mode the testing device tests the protective device faster as in real time, i.e., the operating procedure of the protective device is tested in a period which is shorter than the operating period which is required if the protective device is conducting the operating procedure for protecting the power grid.

The embodiments of the present invention are, for example, adapted for testing a protective relay with which a power grid is protected from a failure. Furthermore, the present invention is not limited to the above-described embodiments, but can be used in other applications where an operating procedure can be tested in a shorter time period as the regular operating period of the operating procedure.

Although specific features described in the above summary and in the following detailed description are described in connection with specific embodiments, it is to be understood that the features of the embodiments described can be combined with each other unless it is noted otherwise.

### BRIEF DESCRIPTION OF THE SEVERAL VIEWS OF THE DRAWINGS

Hereinafter, exemplary embodiments of the invention will be described with reference to the drawings.

FIG. 1 depicts a testing device according to an embodiment of the present invention which is coupled to a protective relay according to an embodiment of the present invention via a power grid and an analog interface.

FIG. 2 depicts a testing device according to an embodiment of the present invention, which is coupled to a protective relay according to an embodiment of the present invention via a power grid and a digital interface.

### DETAILED DESCRIPTION OF THE INVENTION

In the following, exemplary embodiments of the present invention will be described in detail. It is to be understood that the following description is given only for the purpose of illustrating the principles of the invention and it is not to be taken in a limiting sense. Rather, the scope of the invention is defined only by the appended claims and is not intended to be limited by the exemplary embodiments hereinafter.

It is to be understood that in the following detailed description of the embodiments, any direct connection or coupling between functional blocks, devices, components or other physical or functional units shown in the drawings or description herein could also be implemented by an indirect connection or coupling. Same reference signs in the various instances of the drawings refer to similar or identical components.

It is further to be understood that the features of the various exemplary embodiments described herein may be combined with each other unless specifically noted otherwise.

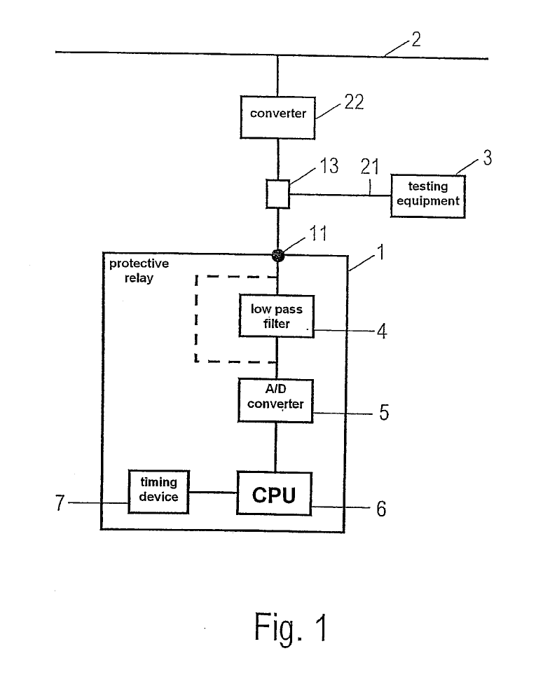

FIG. 1 shows schematically a protective relay 1 which is coupled to an electrical power grid 2 via an analog interface 11 and by means of a converter 22. The protective relay 1 verifies the currents and voltages on the power grid 2. As soon as the protective relay 1 detects a failure, the protective relay 1 activates a power switch (not shown) to decouple a part of the power grid 2 in which the failure is present from the remaining part of the power grid 2.

For testing, if a failure is present in the power grid 2, the data to be tested (currents and voltages) are filtered by a low pass filter 4 and then digitalized by an A/D converter 5. The protective relay 1 comprises a CPU 6 and a timing device 7 for analyzing the digitalized data by means of a test algorithm. The timing device 7 may be realized by a program executed on the CPU 6. The timing device 7 measures or determines specific periods or time durations for testing by means of the protective relay 1, if a specific erratic behavior is still present in the power grid 2 after a predetermined period, and the protective relay 1 reacts in this case accordingly.

For testing the protective relay 1 the protective relay 1 is coupled with a testing equipment 3 via a change over switch 13 and a testing connection 21. The change over switch 13 is adapted to couple the protective relay 1 either to the converter 22 and thus to the power grid 2 or with the test equipment 3 via the test connection 21. It shall be noted that such a change over switch need not to be present practically.

During the testing operation the testing equipment 3 switches the protective relay 1 in a specific test mode, in which the protective relay 1 bypasses the low pass filter 4 such that also high frequency data streams from the testing equipment 3 can be processed by the CPU 6 of the protective relay 1 during the tests. Furthermore, the testing equipment 3 instructs the timing device 7 to run faster such that time periods measured or predetermined from the timing device 7 are shortened compared to the regular operation or the real time. The regular operation means an operation in which the protective relay 1 is not tested, but exclusively used for supervising the power grid 2.

Furthermore, the testing equipment 3 may instruct the protective relay 1 (and especially the CPU 6) to operate as a whole faster than in the regular operation for testing the operating procedures to be tested by the testing equipment 3 faster, thus requiring less time for the test of the protective relay 1.

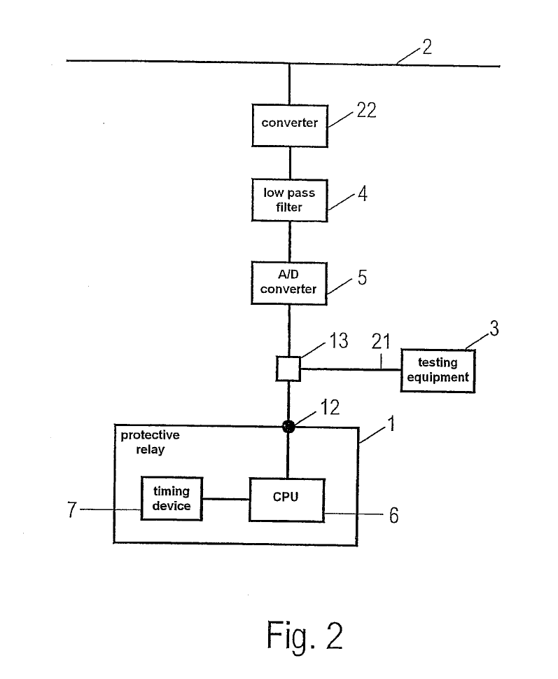

In FIG. 2 another embodiment of a protective relay 1 and a testing equipment 3 is schematically depicted. The embodiment shown in FIG. 2 corresponds basically to the embodiment shown in FIG. 1 and therefore the same reference signs are used and only the differences between the embodiments shown in FIG. 1 and FIG. 2 are described in detail. Compared with the embodiment shown in FIG. 1 the protective relay 1 of the embodiment of FIG. 2 comprises a digital interface 12. Therefore, the protective relay 1 of FIG. 2 does not comprise a lower pass filter 4 and an A/D converter 5 as these components are present on the side of the converter 22. The low pass filter 4 and the A/D converter 5 may be integrated into the converter 22.

The digital interface 12 may be a standardized interface, for example an interface according to IEC 61850-9-2. Therefore, specific tests of the protective relay 1, in which digital test patterns from the test equipment 3 are supplied to the protective relay 1 and corresponding digital test replies from the protective relay 1 are transmitted back to the testing equipment 3, can be conducted much faster as it is possible in connection with an analog interface, at which the test patterns and the test replies have to be converted into an analog signal form from the testing equipment 3 and the protective relay 1, respectively, before they are transmitted.

The embodiments of the protective relay 1 and the testing equipment 3 depicted in FIG. 1 and FIG. 2 are adapted to support two operating modes each. In the first operating mode the protective relay 1 is tested in real time, which means that the test of an operating procedure of the protective relay 1 takes the same time as this operating procedure takes in a regular operation of the protective relay 1. In this first operating mode the testing equipment 3 works such that the tests are supplied to the protective relay 1 in a time period corresponding to a regular operation of the protective relay 1. In the second operating mode the protective relay 1 is tested faster, which means that the test of an operating procedure of the protective relay 1 requires less time than the time required for the operating procedure of the protective relay 1 in the regular operation of the protective relay 1. This means that in the second operative mode the protective relay 1 works faster and additionally also the testing equipment 3 works in the second operating mode faster by providing the tests to the protective relay 1 faster and by evaluating the tests faster.

While exemplary embodiments have been described above, various modifications may be implemented in other embodiments. For example, instead of the protective relay of the above-described embodiments any other kind of protective device may be tested utilizing the above-described test procedure.

Finally, it is to be understood that the embodiments described above are considered to be comprised by the present invention as it is defined by the appended claims.

What is claimed is:

1. A method for testing a protective device for a power grid, comprising
testing an operating procedure of the protective device, an operation of the operating procedure requiring a predetermined operating period when the protective device is used for protecting the power grid,
said testing of the operating procedure of the protective device comprising testing the operating procedure in a shorter time period than the predetermined operating period of the operating procedure.

2. The method according to claim 1, further comprising operating a timing device of the protective device in an accelerated manner for testing the protective device.

3. The method according to claim 1, wherein the protective device comprises a protective relay.

4. The method according to claim 1, further comprising switching the protective device into a test mode for testing the protective device.

5. The method according to claim 1, further comprising, during testing the protective device, bypassing a low pass filter of the protective device, the low pass filter coupling the protective device to the power grid.

6. The method according to claim 1, wherein the protective device comprises an interface, the interface being adapted to couple the protective device to the power grid for protecting the power grid or to test the protective device, and wherein the interface is analog or digital.

7. The method according to claim 1, further comprising supplying at least one sample to the protective device as soon as it is detected that the protective device is able to process at least another sample.

8. The method according to claim 1, wherein said testing of the protective device comprises applying of corresponding test currents or test voltages to the protective device and verifying of algorithms processed in the protective device, and wherein said verifying of the algorithms comprises verifying of parameters.

9. A method for testing a protective device for a power grid, comprising testing an operating procedure of the protective device, an operation of the operating procedure requiring a predetermined operating period when the protective device is used for protecting the power grid, said testing of the operating procedure of the protective device comprising testing the operating procedure in a shorter time period than the predetermined operating period of the operating procedure by operating a timing device of the protective device in an accelerated manner.

10. A protective device for a power grid, wherein the protective device comprises a timing device, wherein the protective device is adapted to execute an operating procedure, the operating procedure requiring a predetermined operating period during an operation of the protective device for protecting the power grid, and wherein the protective device is switchable into a test mode, in which the protective device operates the timing device in an accelerated manner such that the operating procedure is testable in a shorter period than the operating period of the operating procedure.

11. The protective device according to claim 10, wherein the protective device comprises an interface, the interface being adapted to couple the protective device to the power grid for protecting the power grid or to test the protective device, and wherein the interface comprises an analog or a digital interface.

12. The protective device according to claim 10, wherein the protective device is adapted to test the operating procedure of the protective device, wherein the operating procedure is tested in a shorter period than the operating period of the operating procedure, and wherein the timing device of the protective device is operated in an accelerated manner for testing the protective device.

13. A testing device for testing a protective device for protecting a power grid, wherein the protective device comprises a timing device, wherein the protective device is adapted to perform an operating procedure, the operation of the operating procedure requiring a predetermined operating period during an operation of the protective device for protecting the power grid, wherein the protective device is reconfigurable into a test mode, in which the protective device operates the timing device in an accelerated manner such that the operating procedure is testable in a shorter period than the operating period of the operating procedure.

14. The testing device according to claim 13, wherein the testing device is configured such that the testing device is selectively switchable into a first test mode, in which the testing device tests the protective device in real time, and a second test mode, in which the testing device tests the protective device faster than in real time.

15. The testing device according to claim 13, wherein the testing device is adapted to test the operation procedure of the protective device and wherein the operating procedure is tested in a shorter period than the operating period of the operation procedure.
